(19) United States
(12) Patent Application Publication
(10) Pub. No.: US 2006/0082846 A1
(43) Pub. Date: Apr. 20, 2006

(54) Image processing apparatus, image processing program

(75) Inventors: Jun Sakakibara, Koto-ku (JP); Hirokazu Shoda, Yokohama-shi (JP); Kunihiko Miura, Hiratsuka-shi (JP); Koji Tanimoto, Tagata-gun (JP); Koji Kawai, Tagata-gun (JP); Naoyuki Misaka, Sunto-gun (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/226,353

(22) Filed: Sep. 15, 2005

(30) Foreign Application Priority Data
Oct. 20, 2004 (JP) 2004-305320

(51) Int. Cl. G03F 3/08

(52) U.S. Cl. 358/518

(57) ABSTRACT

The present invention provides a technology by which a fairly good monochromatic image without any picture quality deterioration can be obtained from a color image original. An image forming apparatus according to the present invention includes a luminance information acquiring portion adapted for acquiring luminance information of pixels forming an image; a color information acquiring portion adapted for acquiring color information of pixels forming the image; and a luminance information correcting portion adapted for executing a correction of said luminance information of pixels acquired by said luminance information acquiring portion based on said color information of pixels acquired by said color information acquiring portion.

### BACKGROUND OF THE INVENTION

1. Field of the Invention

The present invention relates to an image processing apparatus, an image processing program which are adapted for reading a color image and then obtain a monochrome image.

2. Description of the Related Art

In a traditional art, a CCD line sensor for use in a reduction optical system is commonly known that there are two sensor types, one composed of a single-column CCD line sensor and another composed of plural CCD line sensors arrayed in three columns (three-column CCD line sensor), each CCD line-senor having one of color filters: Red (R), Green (G) and Blue (B) arranged thereon.

The sensor composed of the single-column CCD line sensor is in principle used for reading a monochromatic original. When a color original is read by using such three-column CCD line sensor, a reading method using three light sources each having a spectral characteristic of one of R, G, and B is employed by sequentially turning on the three light sources to read color image information of the color original such that the color information is divided into three color (R, G, B) information. Also, there is proposed another reading method using a light source of while color as a spectral characteristic where at least one of three color filters (R, G, B) can be disposed in an optical path between the light source and the three-column CCD line sensor so as to be switchable from one of the three color filters to another and then divide the white light into three color information incident into the three-column CCD line sensor.

The three-column CCD line sensor as described above is essentially employed for reading a color original, together with a light source, in this case, having a specific spectral characteristic which is enough to cover the visible light range from 400 nm to 700 nm and color filters being disposed on the front sides of respective CCD line sensors to obtain divided color information of R, G, B.

On the other, when the monochromatic original is read by using this three-column CCD line sensor, two approaches have been proposed. A first approach is to use an output from one of three CCD line sensors (an output of the CCD line sensor for G is generally used for the purpose of surely reading a vermilion impress). A second approach is to use all of outputs from the three CCD line sensors for producing white/black information therefrom.

Furthermore, the related art is exemplified by the disclosure of Japanese Patent Laid-Open No. 2003-125173.

In the event that an original is read by a commonly-used monochromatic scanner without any color filters to be disposed on light receiving surfaces of the CCD line sensors, a reflected light from the original is incident on the CCD line sensors, as a result of which it is possible to read luminance variation of the original but impossible to read any color information therefrom. Accordingly, when information of red color is formed on the original having a base surface of blue color, it is impossible to discriminate between blue and red colors commonly having the same reflectance on the original, but it being dependent on the spectral characteristic of the light source, thereby disadvantageously dealing with both of blue and red information as the same signal. Therefore, when the color original is read by the monochromatic scanner, there may be partially or completely lack of information. If a duplicating operation to print the information onto a paper is performed by using signals based on such information, there may be raised a problem where characters and/or images are partially or completely omitted from an image on the paper.

Also, in the event that the color original is read by a three-column CCD line sensor in which three color filters of red (R), Green (G) and Blue (B) are disposed on respective front surfaces of three CCD line sensors so as to perform a monochromatic duplication for obtaining a monochromatic image, the three CCD line sensors may potentially regard any two colors of the color original, depending on colors, as the same color. As a result, the three-column CCD line sensor may capture defective information from the color original.

In general, the scanner is configured to read image information by imaging reflective light from the original on the respective CCD line sensors. Therefore, color information is reproduced by using the additive color process of three primary colors of light. Also, there is proposed a method of artificially producing achromatic color by adding wavelength ranges of red, blue and green of color filters on the CCD line sensors. In this case, the chromatic information is obtained from the following equation.

The chromatic information=(Red information+Blue information+Green information)/3

However, according to this processing, when characters of red color are formed on an original having a base surface of blue color, the three CCD line sensors will output as (red:blue:green)=(0:255:0) upon reading of the blue base surface information while they will output as (red:blue:green)=(255:0:0) upon reading of the red character information, as a result of which: the blue base information can be monochromatized as (0+255+0)/3=85; and also the red character information can be monochromatized as (255+0+0)/3=85. Therefore, it can be understood that the monochromatic duplication of the color original as mentioned above will generate the same information, i.e., the same color, relative to the blue information and the red information.

In this manner, even if two information are different in balance (chroma) between read, blue and green, one (color) information may be the same additive result of red, blue and green, as that of another (color) information. These information can be regarded as the same signals for the monochromatic duplication. Then, when this color original is monochromatically duplicated, there is caused a problem where characters and/or images may be partially or completely omitted from the paper.

### SUMMARY OF THE INVENTION

In order to overcome these problems as described above, an object of the present invention is to provide a technique for obtaining a high quality monochromatic image without any image deterioration from a color image original.

In view of the above-mentioned problems, an image processing apparatus according to the present invention, comprising: a luminance information acquiring portion adapted for acquiring luminance information of pixels forming an image; a color information acquiring portion adapted for acquiring color information of pixels forming the image; and a luminance information correcting portion adapted for executing a correction of said luminance information of pixels acquired by said luminance information acquiring portion based on said color information of pixels acquired by said color information acquiring portion.

Also, an image processing program that is executed by a computer according to the present invention, comprises: a luminance information acquiring step adapted for acquiring luminance information of pixels forming an image; a color information acquiring step adapted for acquiring color information of pixels forming the image; and a luminance information correcting step adapted for executing a correction of said luminance information of pixels acquired by said luminance information acquiring portion based on said color information of pixels acquired by said color information acquiring portion.

### BRIEF DESCRIPTION OF THE DRAWINGS

FIG. 1 is a side sectional view showing an image forming apparatus utilizing four CCD line sensors according to an embodiment of the present invention;

FIG. 2 is a schematic diagram showing four CCD line sensors;

FIG. 3 is a schematic diagram showing drive timings and output signals of the CCD line sensors;

FIG. 4 is a schematic diagram showing four CCD line sensors different from those of FIG. 2;

FIG. 5(A) is a block diagram showing an analog processing circuit for processing a signal outputted from the CCD line sensor;

FIG. 5(B) is an illustrative diagram showing an analog waveform to be processed by the analog processing circuit;

FIG. 6 is a block diagram showing a control circuit system relative to the CCD line sensor;

FIG. 7(A) is a schematic diagram showing a digital copying machine comprising a scanner portion 60 and a printer portion 70 adapted for forming a full-color image on a paper;

FIG. 7(B) is a schematic diagram showing a digital copying machine comprising a scanner portion 60 and a printer portion 70 adapted for forming a monochromatic image on a paper;

FIG. 8 is a conceptional view showing a copying machine comprising a image reading apparatus 60 and the printer portion 70;

FIG. 9 is a schematic diagram showing a detailed configuration of an image processing portion (corresponding to a processing portion of this invention);

FIG. 10 is a block diagram illustrating a detailed configuration of a discriminating portion 213;

FIG. 11 is a schematic diagram illustrating a 3×3 filter matrix for an edge detection;

FIG. 12 a schematic diagram illustrating the result of a character region determination;

FIG. 13 is a schematic diagram illustrating a conception of a hue signal;

FIG. 14 is a schematic diagram illustrating a sampling region in a sample extracting portion;

FIG. 15 is a schematic diagram illustrating a signal output in a color character determining portion;

FIG. 16 is a schematic diagram illustrating a configuration of a monochromatic correcting portion;

FIG. 17 is a schematic flow chart of a processing flow for each operation of various modes;

FIG. 18 is a detailed flow chart for illustrating the processing operations in the steps S2 and S3 as shown in FIG. 17;

FIG. 19(A) shows an example of base concentration correction tables;

FIG. 19(B) shows another example of base concentration correction tables;

FIG. 19(C) shows yet another example of base concentration correction tables;

FIG. 19(D) shows an example of character concentration correction tables;

FIG. 19(E) shows another example of character concentration correction tables;

FIG. 19(F) shows yet another example of character concentration correction tables;

FIG. 20(A) shows an example of base concentration correction tables;

FIG. 20(B) shows another example of base concentration correction tables;

FIG. 20(C) shows yet another example of base concentration correction tables;

FIG. 20(D) shows an example of character concentration correction tables;

FIG. 20(E) shows another example of character concentration correction tables;

FIG. 20(F) shows yet another example of character concentration correction tables;

FIG. 21 shows a selective example of base concentration correction tables;

FIG. 22(A) is a schematic diagram illustrating a specific example of advantageous effects occurred during copying operation according to the present invention;

FIG. 22(B) is a schematic diagram illustrating another specific example of advantageous effects occurred during copying operation according to the present invention; and

FIG. 23 is a flow chart illustrating an overall processing flow of the image processing apparatus according to an embodiment according to the present invention.

### DETAILED DESCRIPTION OF THE INVENTION

Hereinafter, an embodiment according to the present invention will be described in detail with reference to the accompanying drawings.

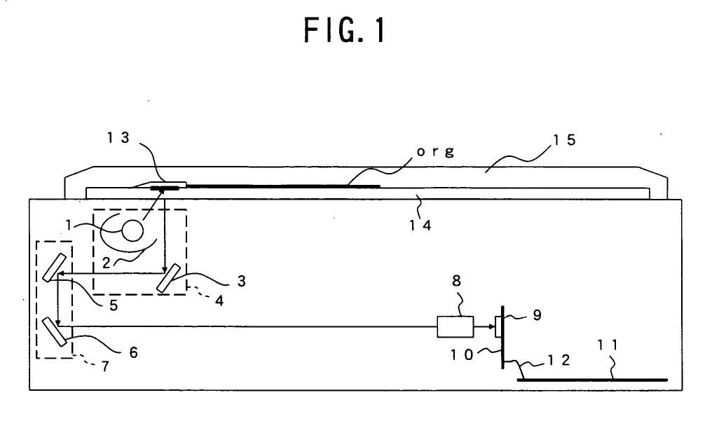

FIG. 1 is a side sectional view showing an image reading apparatus (corresponding to an image processing apparatus) utilizing four CCD line sensors (hereinafter, it is referred to as a “CCD line sensor”).

In this image processing apparatus, an original ORG is placed on the document glass 14 in a facedown fashion and then forced onto the document glass 14 by closing a original-impressing cover 15 which is openably set for fixing the original ORG on the document glass 14.

The original ORG is irradiated by a light source 1 to image its reflective light via a first mirror 3, a second mirror 5, a third mirror 6 and a condenser lens 8 on a front side of the CCD line sensor 9 implemented on a CCD sensor substrate 10. A non-shown carriage driving motor(s) moves a first carriage 4 containing therein the light source 1 and the first mirror 3 and a second carriage 7 containing therein the second and third mirrors 5 and 6 so that the original ORG is scanned with the irradiation from the light source 1. A moving speed of the first carriage 4 is set twice as fast as that of the second carriage 7 so that the length of an optical path between the document glass 14 and the CCD line sensor 9 can be controlled to remain constant.

Thus, the original ORG placed on the document glass 14 is sequentially read one-line by one-line and an optical signal of its reflective light is converted into an analog signal depending on the intensity of the reflective light by the CCD line sensor 9. Subsequently, the converted analog signal is converted into digital signal which then is passed via a harness 12 into a control substrate 11 adapted for handling control signals in association with CCD sensors. In this control substrate 11, a digital signal processing operation is executed in such a manner that a subharmonic distortion due to the condenser lens 8 and/or a harmonic distortion due to sensitivity dispersion of the CCD line sensor 9 can be corrected by a digital signal processing operation such as a shading (distortion) correction method and the like.

It should be noted that the processing operation for converting the analog signal into the digital signal can be executed by the CCD sensor substrate 10 or by the control substrate 11 via the harness 12.

When the shading correction is executed, a reference signal for black and a reference signal for white are required. Specifically, the former black reference signal is set as an output signal from the CCD line sensor 9 on condition that any light is not irradiated onto the CCD line sensor 9 when the light source 1 is extinguished. The latter white reference signal is set as an output signal from the CCD line sensor 9 upon reading of a white reference plate 13 on condition that the light source 1 is lighted. Also, it is a general practice to average signals resulting from reading plural lines in order to reduce adverse influences due to singular point and/or quantization error.

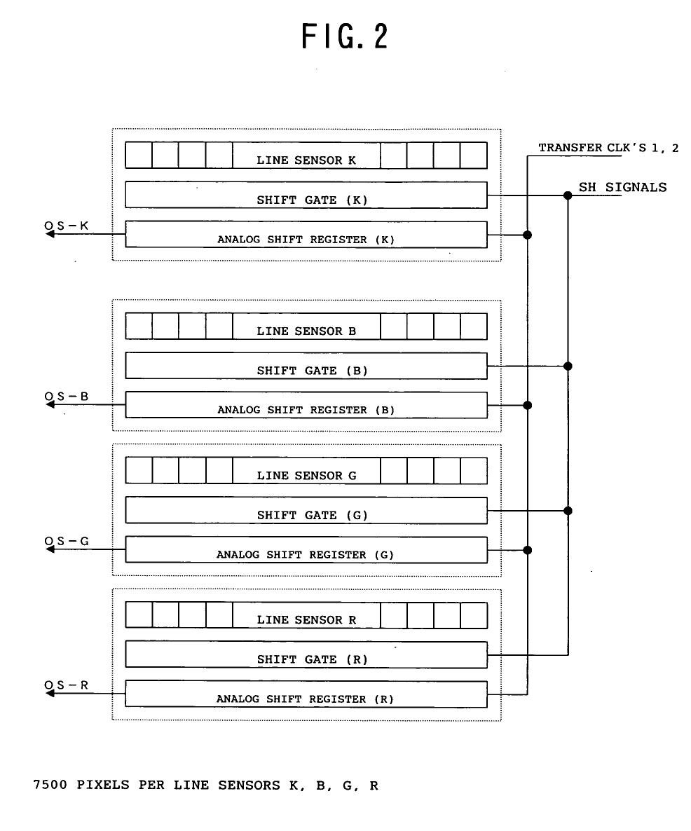

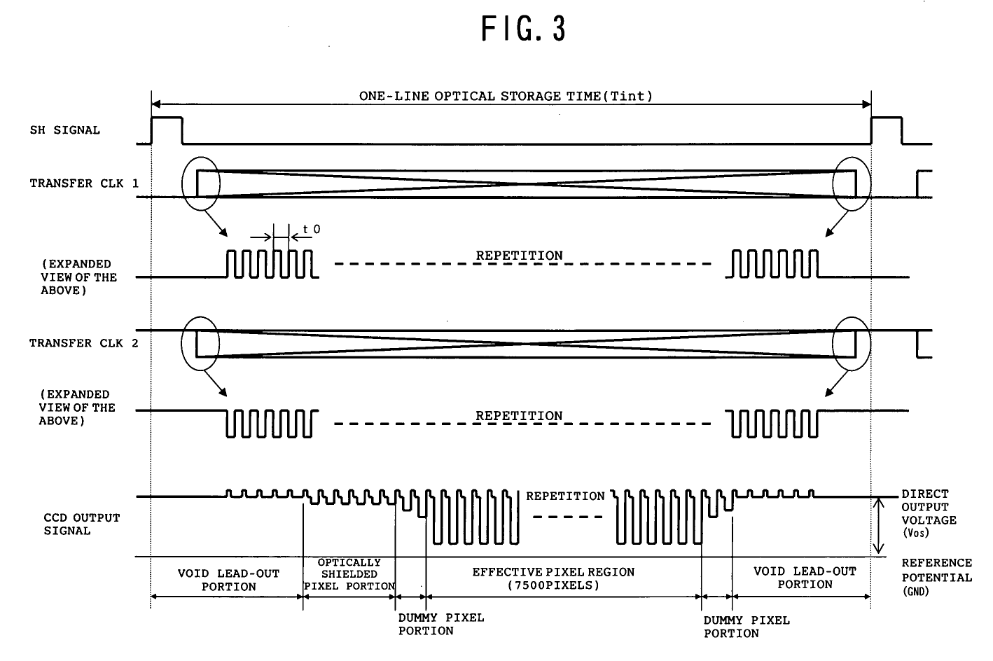

In the following, a configuration and operation of the CCD line sensor 9 will be described with reference to FIGS. 2 and 3.

FIG. 2 shows a four-CCD line sensor example according to an embodiment of the present invention and comprised of a line sensor K having no color filter disposed on its light receiving surface and three line sensors (i.e., a line sensor B, a line sensor G and a line sensor R) having blue (B), green (G) and red (R) color filters on their light receiving surfaces, respectively. These line sensors K, B, G, R are each composed of a photodiode array adapted for executing a photo-electro conversion.

In this case, a line sensor K constructs a luminance information acquiring portion(a first line sensor),and line sensors B, G, R construct a color information acquiring portion (a second line sensor).

In the event that a sheet of the original ORG is of size A4 for example, the original ORG has an area of 297 mm in longitudinal direction and 210 mm in transverse direction. When the original reading operation is executed in a main scanning direction as the longitudinal direction and in a sub scanning direction as the transverse direction, the photodiode array of the CCD line sensor 9 requires at least 7016 pixels as the number of effective pixels (4677 pixels at the time of 400 dpi). In general, a number of sensors are used to afford 75000 pixels (5000 pixels at the time of 400 dpi).

Also, as shown in 3, the CCD line sensor comprises an optically shielded pixel portion at which the photodiode array is partially shielded with aluminum or the like to prevent any light from being incident thereto and which is anterior to the effective 7500 pixels, dummy pixel portions which are located respectively before and after the effective 7500 pixels, and void lead-out portions which are located respectively before and after the effective 7500 pixels. Thus, in order to outwardly output all of electrical charges stored in the CCD line sensor, the required number of transfer CLK's is more than 7500 pixels.

On the assumption that the total number of the optically shielded, void lead-out and dummy pixel portions with the exception of the effective pixel region is 500 pulses in terms of the number of the transfer CLK's, 8000 pulses as a time period of the transfer CLK's are required for outwardly outputting all of charges stored only in one-line (or one-column) of the CCD line sensor. This corresponds to a one-line optical storage time (tINT).

The CCD line sensor is characterized by its output signal which is outputted under the reference of voltage level donning a certain offset with respect to an electrical reference level (reference potential: GND). This voltage level as the reference is referred to as a “direct output voltage (offset level: Vos).

During a low “L” level of a SH signal in the one-line optical storage time (iINT) as shown in FIG. 3, an optical energy irradiated on a CCD line sensor is stored as charges in photodiodes. Then, during a high “H” level of the SH signal, the stored charges are passed through a shift gate adjacent to the photodiodes and transferred to an analog shift register adjacent to the shift gate. After this transfer operation has been completed, the SH signal is turned to its “L” level to operate the shift gate so as to prevent any charges from being leaked out of the photodiodes and restart a charge storing operation at the photodiodes.

The charges transferred to the analog shift register are transferred outwardly by a pixel unit and at a period of the transfer CLK's. Due to this movement, an application of the transfer CLK's is stopped for a time period during which charges are shifted from the photodiodes to the analog shift register via the shift gate by means of the SH signal (see FIG. 3).

Also, in the event that the transfer CLK is normally inputted and that the transfer CLK is stopped in accordance with the SH signal in the interior of the CCD line sensor, the internal charge transfer movement is similar to that as above. In particular, depending on the CCD line sensor, the SH signal and the transfer CLK may be different in their polarities from those as shown in FIG. 3 but internal operations of the CCD line sensor are similar to those as shown in FIG. 3. The time period expended for the transfer CLK's of 8000 pulses does not mean, regardless of a stoppage state of the transfer CLK in accordance with the SH signal, the number of CLK's but the time.

For example, on the assumption that an image transfer frequency of a four-line CCD line sensor 6 is f=20 MHz, a time period of 8000 (CLK's)×(1/20 MHz)=400 μs is expended for outwardly outputting all of charges stored in each line of the four-line CCD line sensor. This time period corresponds to the one-line optical storage time expended for one line in the sub scanning direction of the four-line CCD line sensor.

Hereinafter, an analog signal amplitude outputted from the four-line CCD line sensor 9 will be explained on the condition that the transfer CLKt0: 20 MHz and the one-line optical storage time tINT=400 μs. However, depending on a product specification, there may arise a case which is different in transfer CLK frequency from those as above.

Incidentally, the four-line CCD line sensor is, as described above, comprised of: the line sensor BK having no color filter disposed on its light receiving surface and the three line sensors R, G, B each being a color filter disposed on its light receiving surface. When these line sensors are uniformly irradiated by a light from the light source, the line sensor BK can output an analog signal that is larger in amplitude than that which can be outputted from each of the line sensors R, G, B because each of the line sensors R, G, B has a sensitivity only in a specific wavelength range but the line sensor BK has a sensitivity in a wide wavelength range from less than 400 nm to more than 1000 nm. Here the line sensor BK can comprises a transparent filter additionally.

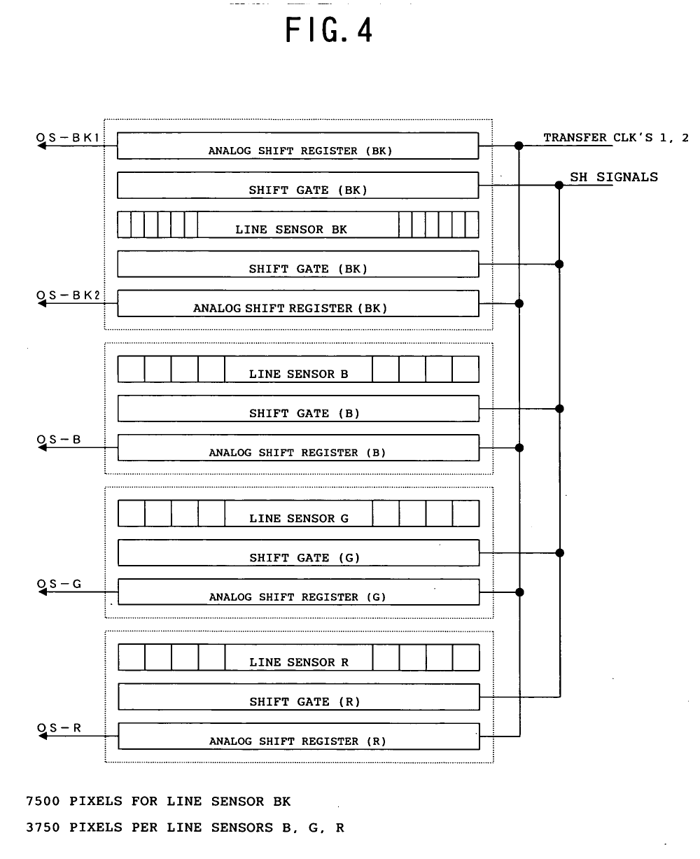

In addition, as shown in FIG. 4, only the line sensor BK adopts a two-system output type by which the stored charges therein are separated into odd-pixels and even-pixels, thereby enabling a speed for reading a monochromatic original or the like by the line sensor BK to be increased. This case is similar in performance to that of a single-system output type as shown in FIG. 3, particularly with respect to output signals, the void lead-out portion, the optically shielded, the dummy pixel portion and the effective pixel region. Further, the line sensor of the two-system output type requires a half of the number of the transfer CLK's expended for transferring all of pixels therein as compared with that of the single-system output type. For example, 7500 of the CLK's are required for transferring all of pixles from the effective pixel region in the case of the single-system output type while, in the two-system output type, only 3750 of the CLK's, i.e., a half of 7500 CLK's, are required. Therefore, it is possible in the two-system output type to shorten the one-line optical storage time of the SH signal as shown in FIG. 3.

Correspondingly, if the number (7500) of the effective pixels of each photodiode set for the line sensors R, G, B having color filters disposed on their light receiving surfaces is reduced to a half of 7500 (3750) and each pixel size is doubled, it is possible to equalize a reading coverage of each of the line sensor R, G, B relative to the line sensor BK. Because there is a large difference in sensitivity whether or not the color filter is disposed on the light receiving surface of the liner-sensor, it is possible to enhance the sensitivity of the line sensor having the color filter disposed on its light receiving surface by enlarging an area for pixels of the liner-sensor.

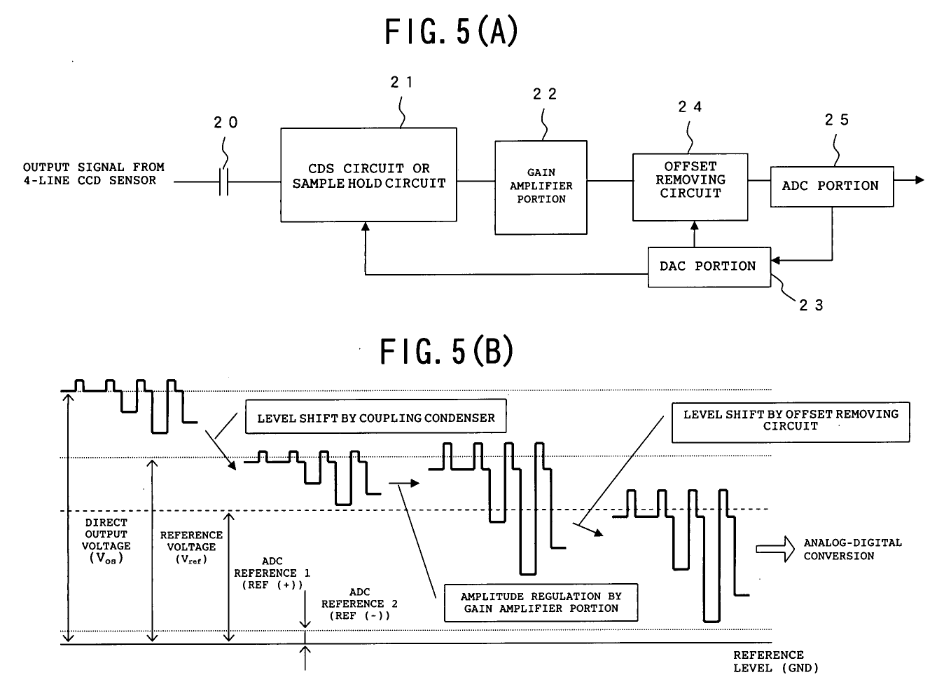

FIG. 5(A) is a block diagram showing an analog processing circuit for processing an analog signal outputted from the CCD line sensor. FIG. 5(B) is an illustrative diagram showing an analog waveform to be processed by the analog processing circuit.

As shown in FIG. 5(A), the analog processing circuit for processing analog signals outputted from the CCD line sensor 9 is generally comprised of: a coupling condenser 20; a correlative double sampling circuit (CDS) or sample hold circuit 21; a gain amplifier portion 22; a digital analog converter (DAC) 23; an offset removing circuit 24 for removing a direct component; and an analog digital converter (ADC) portion 25.

Operations of the above will be described with reference to FIG. 5(B).

Output signals from the CCD line sensor are each outputted as the reference of a direct output voltage (Vos) also as shown in FIG. 3. This direct output voltage (Vos) are different depending on a CCD line sensor as used. In the case of a CCD line sensor employing a voltage source of +12 volts, its output has a dispersion of about 3-8 volts. The coupling condenser 20 is coupled in series thereto for the purpose of removing a direct component of a signal having an uncertain level.

At this time, a potential of the dummy pixel portion or the optically shielded pixel portion is processed to be adjusted within a reference potential (Vref) in order to facilitate the processing in the CDS circuit or sample hold circuit 21.

Then, an analog signal which has been outputted from the CCD line sensor and whose direct component has been removed in the condenser 20 is processed to be adjusted within an input range of the posterior ADC portion 25. At that time, in order to adjust the direct component within the input range, a direct voltage is generated in the DAC portion 23 and then is regulated in the CDS circuit or sample hold circuit 21 serving as the correlative double sampling circuit and the offset removing circuit 24 so as to conform a voltage of the optically shielded pixel portion of the CCD line sensor with that direct voltage.

As shown in FIG. 5(B), a reference voltage at a “H” level side as required for conversion in the ADC portion 25 is set to an ADC reference 1 (ref (+)) and a reference voltage at a “L” level side thereof is set to an ADC reference 2 (ref (−)). The signal processing is executed to fall within these voltage range. At that time, if a signal which is more than the ADC reference 1 (ref (+)) or less than the ADC reference 2 (ref (−)) is inputted into the ADC portion 25, an output from the ADC portion 25 can be saturated. Therefore, the input into the ADC portion 25 must be within the reference range.

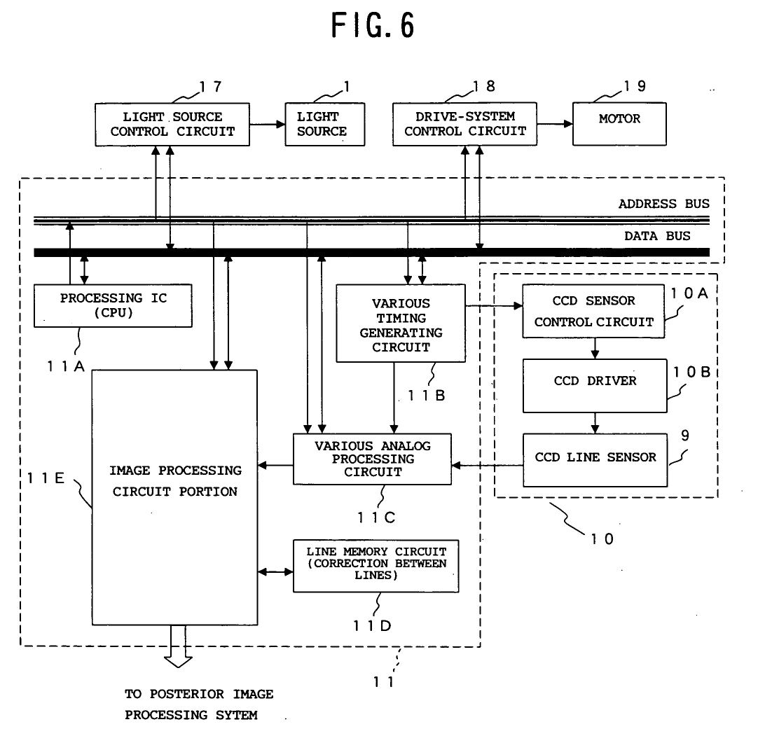

FIG. 6 is a block diagram showing the control substrate 11.

The control substrate 11 is comprised of: a processing IC 11A such as CPU; various timing generating circuits 11B; various analog processing circuits 11C as shown in FIG. 5; a line memory circuit 11D; and an image processing circuit portion 11E.

The processing IC 11A is adapted for controlling a signal processing system of the CCD line sensor 9 and additionally controlling a drive-system control circuit 18. By using control signals from an address bus and a data bus, this drive-system control circuit 18 is adapted for controlling a light source control circuit 17 to control the light source 1 and further for controlling a motor 19 to move the first and second carriages 4 and 7.

The various timing generating circuit 11B is adapted for generating: the SH signal and transfer CLK's as shown in FIG. 3; a signal required for driving the CCD line sensor 9; and a signal required for executing various analog processing operations as shown in FIG. 5. The signal which has been generated by the various timing generating circuit 11B to drive the CCD line sensor 9 is subjected to a timing regulation in a CCD sensor controlling circuit 10A, or inputted into the CCD line sensor 9 via the CCD driver 10B for adjusting a signal amplitude level or shaping waveform. Incidentally, the CCD line sensor control circuit 10A maybe included in the various timing generating circuit 11B.

A output from the CCD line sensor 9 is inputted into the various analog processing circuit 11C to execute a variety of analog processing operations. As shown in FIG. 6, this various analog processing circuit 11C is explained as one of components of the control substrate 11 but may be located on the CCD sensor substrate 10.

In the structure of the CCD line sensor 9, respective line sensors are physically spaced from each other as shown in FIG. 2 or FIG. 4, as a result of which there can arise any dislocation among their reading positions. The line memory circuit 11D is adapted for correcting such a reading position dislocation.

The image processing circuit portion 11E is adapted for controlling the line memory circuit 11D and further adapted for executing various processing operations of a shading correction, an expansion/reduction processing, a LOG transformation and the like by using digitalized image signals. Also, various processing operations of reading the color original and converting its image into monochromatic signals of achromatic color are executed in this image processing circuit portion 11E. These processing operations will be explained in detail later on.

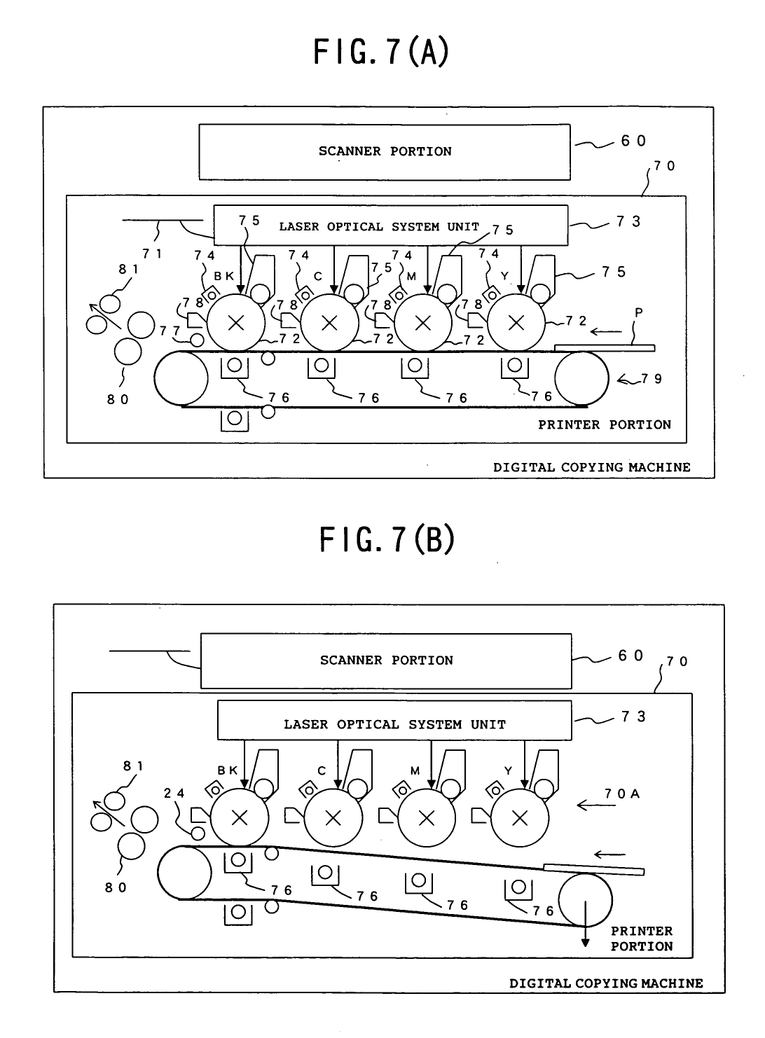

FIGS. 7(A) and 7(B) are schematic diagrams showing a digital copying machine (corresponding to the image forming apparatus and the image processing apparatus according to the present invention) comprising the image reading apparatus (scanner portion 60) and a printer portion 70. This printer portion 70 is an example of image forming apparatuses compatible with full-color image formation. In FIGS. 7(A) and 7(B), there are provided developing systems of Y (yellow), M (magenta), C (cyan), K (black) independently from each other. FIG. 7(A) shows an internal state of the digital copying machine (the image processing apparatus which comprises the image forming portion corresponding to this invention) for forming a full-color image. FIG. 7(A) shows a state in which a full-color image is formed. When a monochromatic image is formed according to the present invention as shown in FIG. 7(B), only K-developing system is gotten in contact with a print medium sheet to form the image on the print medium sheet while the other Y-, M- and C-developing system are not in contact with the print medium sheet.

In addition, the printer portion(the image forming apparatus) 70 is comprised of: an image processing substrate 71 adapted for executing required processing operations for an image formation, e.g., for converting information read by the CCD line sensor 9 into a control signal for a light emitting element such as a non-shown semiconductor laser; a laser optical system unit 73 on which the light emitting element such as the non-semiconductor laser is mounted for forming a latent image on a photosensitive drum 72; and an image forming portion 70A. This image forming 70A is comprised of: the photosensitive drums 72; electrical chargers 74; developers 75; transfer chargers 76; separation chargers 77; cleaners 78; a sheet transporting mechanism 79 for transporting a sheet P; and fixer 80, which are all required for the image formation by the electrophotographic process.

The print medium sheet P on which an image has already been formed in the image forming portion 70A is discharged into a discharging tray (not shown) by discharging rollers 81 for discharging the print medium sheet P outside of the machine.

Additionally, another example of the image forming apparatuses compatible with full-color image formation may be configured for forming an image on a single photosensitive drum directly by the four Y-, M-, C-, K-developers disposed around the single photosensitive drum. Yet another example of the image forming apparatus compatible with full-color image formation may be configured for temporarily forming an image on an intermediate member by the four Y-, M-, C-, K-developers and then transferring the image onto the photosensitive drum. Further example of the image forming apparatuses compatible with full-color image formation may be configured for temporarily forming an image on an intermediate member by the four Y-, M-, C-, K-developers and then transferring the respective images onto the photosensitive drum.

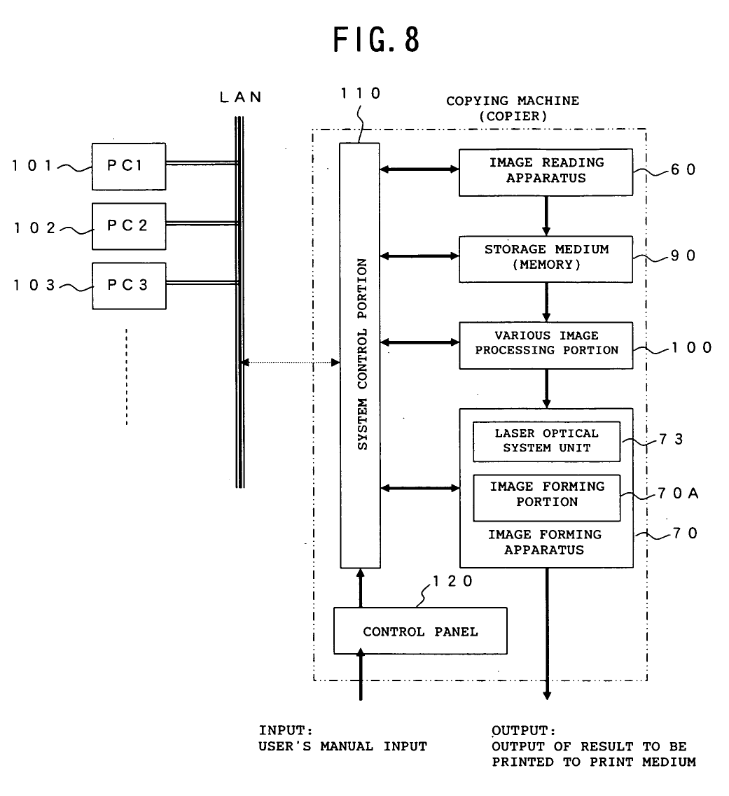

FIG. 8 is a conceptional diagram showing the copying machine (corresponding to the image processing apparatus) comprising the image reading apparatus 60 and the image forming apparatus 70.

This system comprises; the image reading apparatus (scanner portion 60); a memory medium 90 serving as a storage medium; a various image processing portion 100; and an image forming apparatus (a printer portion 70) including therein a laser optical system unit using a semiconductor laser and an image forming portion 70A for forming a toned image by the electrophotographic process, all of which are controlled by a system control portion 110 and a control panel 120 by which a user directly perform input operations.

In this case, there are provided a singular mode in which this copying machine can be used singularly, a network printer mode in which this copying machine can be used as a network printer from external computers PC101, PC102, PC 103, . . . by connecting itself to a network, and a network scanner mode in which this copying machine can be used as a network scanner from external computers PC101, PC102, PC 103, . . . by connecting itself to a network.

When this copying machine is used in the singular mode, firstly a user places an original ORG to be copied on the image reading apparatus (scanner portion A) and conducts a desired setting on the control panel 120. The control panel 120 comprises (but not illustrated): an auto color button for making the apparatus detect whether the original ORG is a monochromatic or color original; full-color and black buttons for making the user set a kind of the original beforehand; a copy/scanner button for making the user use this apparatus as a copier or as a scanner; a display portion for displaying thereon an expansion/reduction operation and the set number of sheets; a setting portion having number keys 0, 1, 2, . . . 9 for inputting the desired number of sheets to be copied and a clear button for clearing the inputted and set number of sheets; a reset button for initializing the condition which has been set on the control panel; a stop button for stopping a copying operation or scanning operation; and a start button for starting the copying operation or scanning operation.

There is no problem where the control panel 120 is constructed, for example, by a touch panel overlaid on a liquid crystal display (LCD) with various buttons as described above.

The copying operation is started by setting the original ORG, closing the original-impressing cover 15, setting a kind and size of the original and the number of sheets to be copied and then pressing the start button. Hence, an image information read by the scanner portion 60 is temporarily stored in the memory 90 as a storage device. This memory 90 is composed of a page memory having a more capacity than that capable of storing all of image information of the maximum copiable size. The image signal outputted from this memory 90 is subjected to various processing operations such as expansion, equivalent amplification, reduction, and gradation correction in the various image processing portion 100 at a posterior stage to the memory 90, and converted into a control signal for the semiconductor laser to be inputted into the posterior laser optical system unit 73.

In the laser optical system unit 73, an optical output from each semiconductor laser by means of the image signal is irradiated onto the photosensitive drum 72 in the image forming portion 70A. The image forming portion 70A is adapted for forming an image according to the electrophotographic process.

In the network printer mode, the image information is outputted from the external computer(s) by a network connection via the system control portion 110. During this operation, the image information, e.g., outputted from the PC 101 as an external computer, is stored in the memory 90 via the system control portion 110. Then, similarly to that of the copying operation, the image is printed on the print medium of sheet P and outputted outwardly by the image forming portion 70A in the printer portion 70.

In the network scanner mode, the image information read by the scanner portion 60 is outputted as an image into a network connected computer via the system control portion 110.

For example, the user places the original ORG on the scanner portion 60, sets a kind and size of the original and then sets whether this is the copying operation or the scanner operation. Further, the user sets an address of the network connected computer PC 101 as a destination of the image information and presses the start button to start this operation. The image information read by the scanner portion 60 is stored in the memory 90 and then subjected to a desired processing operation for compression such as JPEG or PDF format in the various image processing portion 100 at a posterior stage of the memory 90. The compressed image information is via the system control portion 110 transferred through the network to the external computer PC 101.

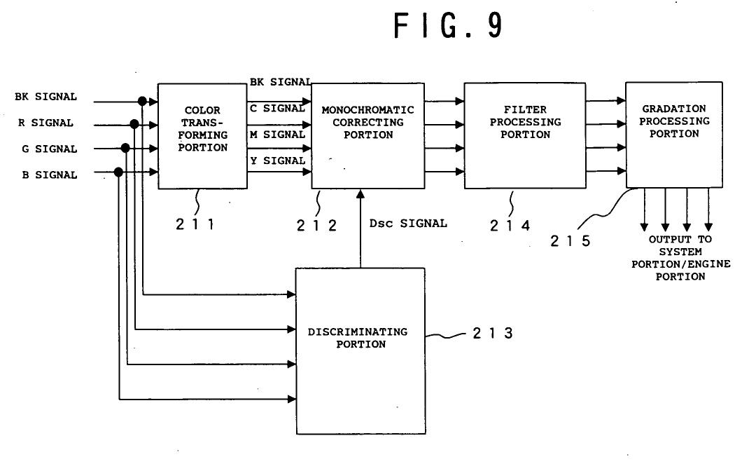

Next, a configuration of the image processing portion according to the embodiment of the present invention (a basic portion of the image processing apparatus in the present invention) will be described with reference to FIG. 9. The image processing portion comprises: a color transforming portion 211; a monochromatic correcting portion (corresponding to a luminance information correcting portion) 212; a discriminating portion 213; a filter processing portion 214; and a gradation processing portion 215.

In the above configuration, a color signal (corresponding to color information) (RGB signals) and a monochromatic signal (corresponding to luminance information) (BK signals) are inputted into the color transforming portion 211 at which its luminance information is transformed in concentration (gray-scale) into a Cyan signal, a Magenta signal, a Yellow signal, and a BK signal. C/M/Y/BK signals thus transformed in concentration are inputted into the monochromatic correcting portion 212.

As described in detail later on, the monochromatic correcting portion 212 selects a concentration correction table (a correction table) based on an discrimination signal Dsc from the discriminating portion 213 to correct the BK signal. Signals outputted from the monochromatic correcting portion 212 are subjected to LPF (Low Pass Filter) processing operation and HPF (High Pass Filter) processing operation in the filter processing portion 214 and then outputted into the gradation processing portion 215. In the gradation processing portion 215, there are provided screens for respective color signals. The filter processing portion 214 and the gradation processing portion 215 serve as a monochromatic image producing portion(an image forming portion) for producing a monochromatic image.

The discriminating portion 213 is adapted for outputting an discrimination signal Dsc of character color and background color to input it into the monochromatic correcting portion 212. The discriminating portion 213 and a line sensors above mentioned constitute a luminance information acquiring portion and a color information acquiring portion of this invention. Signals for respective colors outputted to a system portion and an engine portion is used to form an image and then output the image by the engine portion.

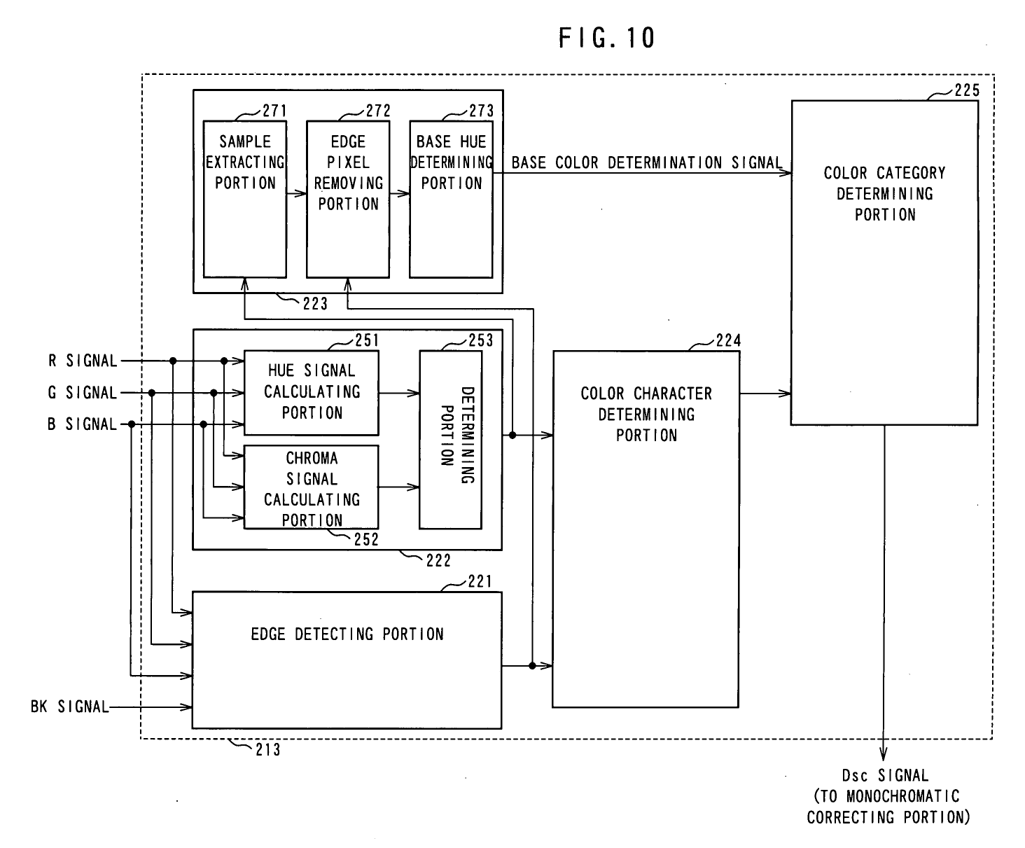

With the above explanation in mind, a configuration of the discriminating portion 213 will be described with reference to FIG. 10. The discrimination porting 213 (which constitutes a basic portion of the discriminating portion which discriminates the first region and the second region of this invention)is comprised: an edge detecting portion (corresponding to a region discriminating portion) 221; a hue determining portion 222; a base color determining portion 223; a color character determining portion 224; and a color category determining portion 225. These determining portion 222, 223, 224, 225 constitute a color information acquiring portion.

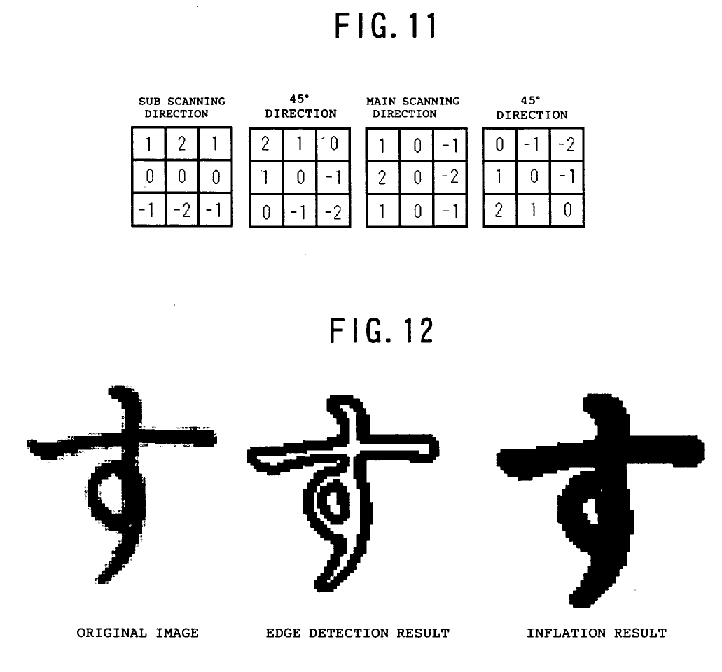

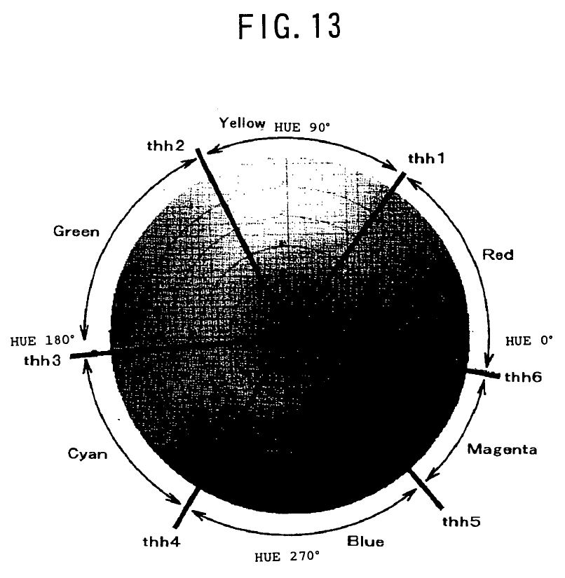

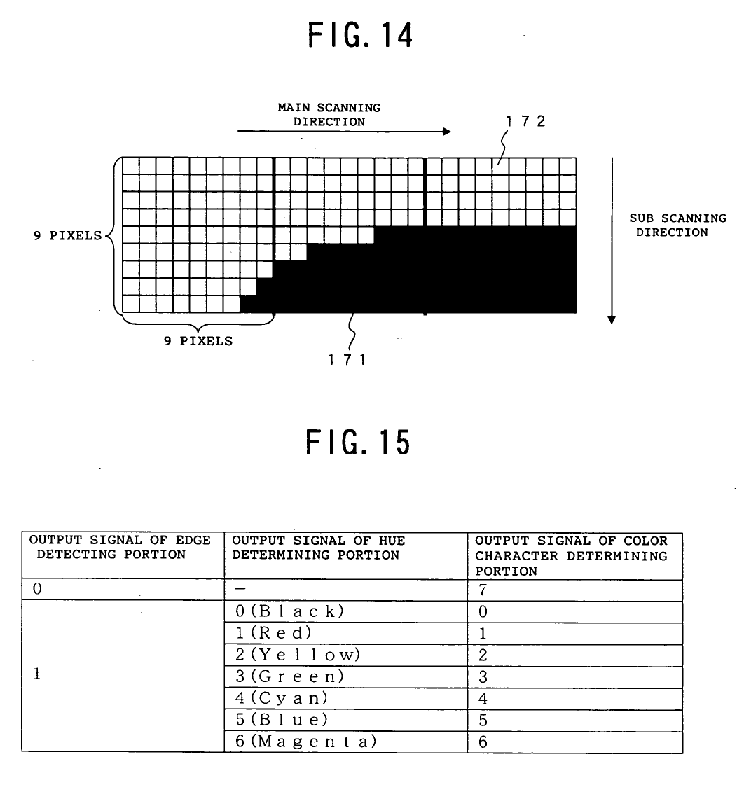

The edge detecting portion 221 is adapted for detecting an edge within the image based on the RGB signals and BK signal as input signals. The edge detecting portion 221 is also adapted for calculating an edge characteristic amount in a vertical direction, in a horizontal and in diagonal directions (two kinds of +45° directions) by performing 3×3 matrix operation using Sobel filters as shown in FIG. 11. The calculated edge characteristic amount is compared to a threshold value Th to discriminate a character region. That is, the region discriminating portion is adapted for discriminating a specific region on the image and a peripheral region adjacent to the specific region based on the acquired luminance information and the color information.

In general, this threshold value Th is set to a value suitable for a character discrimination based on the MTF (Modulation Transfer Function) characteristic of the scanner. As shown in FIG. 12, the resultant character region thus discriminated is inflated in the interior of a character so that not only edge portion but also a character region in the interior of the character can be discriminated.

More specifically, the directionality in concentration change with respect to a position of the detected edge is detected and a dispersion value of 3×3 pixels is calculated with respect to a region at which the concentration is high. Then, if this dispersion value is less than a threshold value, the detection result of the character is inflated. This processing operation is similarly executed to a position of an edge paired with the previously detected edge so as to inflate the interior of the character. The inflation processing operations thus executed result in an output of “1” relative to a character region and an output of “0” relative to a non-character region.

In addition, the edge detection is executed by using Sobel filters but the present invention should not be limited to Sobel filters. In spite of Soble filters, another edge detection method such as Laplacian filters may be used.

Next, the hue determining portion 222 will be described in detail. This hue determining portion 222 is adapted for calculating the hue/chroma based on RGB signals. Specifically, from the RGB signals, a hue signal calculating portion 251 and a chroma signal calculating portion 252 calculate the hue signal/chroma signal by using the following operation equations:

hue signal = tan⁻¹(R − G)/(G − B)) × 180/p
chroma signal = Max(|R − G|, |G − B|).

outputs a larger one of two absolute values of (R-G) and (G-B) by comparison between their two absolute values. A determining portion 253 determines the hue based on the calculated color signal/chroma signal. Specifically, the calculated chroma signal is compared to a threshold value the and then executes the determination of “chromatic color” or “black (achromatic color)” based on the following determination conditions:
if chroma signal<thc, then it is black; and
if chroma signal=thc, then it is chromatic color.

Then, if this determination indicates the achromatic color, a “Black hue” is outputted. Also, if this determination indicates the chromatic color, its hue is determined by using the hue signal. The hue signal can be expressed at an angle over a range between 0° and 360°. Thus, the hue is determined based on the hue signal expressible by an angle by using the following condition equations:

if thh6 < hue signal = thh1, then it is Red;
if thh1 < hue signal = thh2, then it is Yellow;
if thh2 < hue signal = thh3, then it is Green;
if thh3 < hue signal = thh4, then it is Cyan;
if thh4 < hue signal = thh5, then it is Blue; and
if thh5 < hue signal = thh6, then it is Magenta.

is a threshold value for allocating the hue signal to any one of hue regions.

From the determinations as above, a hue for each pixel can be determined. After the hue determination, “0” in the case of Black,. “1” in the case of Red, “2” in the case of Yellow, “3” in the case of Green, “4” in the case of Cyan, “5” in the case of Blue, and “6” in the case of Magenta are outputted as the hue determination results.

Next, the base color determining portion 223 will be described in detail. The base color determining portion 223 is comprised: a sample extracting portion 271; an edge pixel removing portion 272; and a base hue determining portion 273. The sample extracting portion 271 is adapted for performing a sampling by 9 pixels in a main scanning direction in a 9×9 pixel block.

After the sampling by a 9×9 pixel block, the edge removing portion 272 is adapted for removing edge pixels 171 (character pixels) existed in a 9×9 pixel block by using the edge detection result. The base hue determining portion 273 is adapted for counting how many pixels of respective hues exist in the base pixels 172 and determining a hue having the maximum count value as the block hue.

Based on this hue determination, the base color is determined. The base color determination results are outputted as follows: “0” in the case of Black; “1” in the case of Red; “2” in the case of Yellow; “3” in the case of Green; “4” in the case of Cyan; “5” in the case of Blue; and “6” in the case of Magenta. If there exist no edge pixels in the 9×9 pixel block, it is determined as a picture region to output “7” as the base color determination result.

Next, the color character determining portion 224 will be described in detail. The color character determining portion 224 is configured to combine the edge detection result with the hue determination result to determine a color of the character region as shown in FIG. 10. More specifically, respective signals are outputted based on a table as shown in FIG. 15.

In FIG. 15, if an output signal of the edge detecting portion 221 is “0 (non-character)”, then “7” is outputted regardless of the output of the hue determining portion. If the output signal of the edge detecting portion 221 is “1”, then an outputted value is changed based on the output signal of the hue determining portion.

Next, the color category determining portion 225 will be described in detail. The color category determining portion 225 is adapted for synthesizing the color character determination result and the base color determination result to output a Dsc signal of 6 bits. Specifically, “0” through “6” of the base color determination results are allocated to its three highmost bits and “0” through “7” of the color character determination results are allocated to its three lowmost bits.

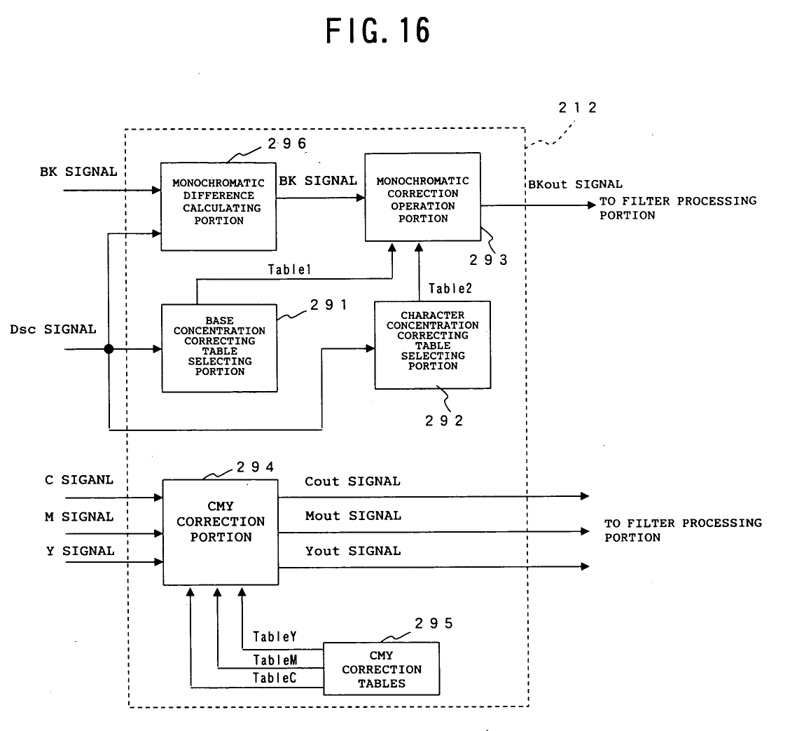

Next, the monochromatic correcting portion 212 will be described in detail. The monochromatic correcting portion 212 is configured as shown in FIG. 16, and is comprised of: a monochromatic difference calculating portion 296; a monochromatic correction operation portion 293; a base concentration correcting table selection portion 291; a character concentration correcting table selection portion 292; and CMY correcting portion 294.

The monochromatic difference calculating portion 296 is adapted for referencing remarkable pixels in the main scanning direction and its fore-and-aft adjacent 5 pixels (11 pixels in total) and calculating mean value of BK signals for each character region and each base region based on the Dsc signal to obtain their difference values. If the difference value is less than a previously-set predetermined threshold value, then it is decided that a difference of concentration between the character region and the base region of the BK signals is small. At this time, any offset is added to each of BK signals depending on the hue of the character region and the hue of the base region. Specifically, in the monochromatic correcting portion 212, the luminance information correcting portion corrects the luminance information of pixels of at least one of the specific region and the peripheral region so that a difference in pixel luminance value becomes more than a predetermined threshold value, when the difference in luminance value of pixels forming the specific region and the peripheral region within a portion adjacent to both regions is turned out to be less than the predetermined threshold value.

For example, in the event that the hue of the base region is blue and the hue of the character region is red, a value “−20” is added to the BK signal of the base region and a value “+20” is added to the BK signal of the character region. If a difference value of the BK signals is larger than a predetermined threshold value, any addition operation is not performed.

The monochromatic correcting portion 212 stores 7 kinds of tables for correcting the base concentration and 7 kinds of tables for correcting the character concentration to select any one of such tables by the Dsc signal. Specifically, in case of non-character is determined by the Dsc signal( three lowest bits of the signal show 7), the correction table of the base concentration is selected by its three highmost bits of the Dsc signal. An inputted BK signal will be corrected in concentration by using the selected correction table in the monochromatic correcting operation portion 293 by the following operation equation:
BKout=Table1[Dsc>>3][BK],
wherein the BKout indicates an output signal after the concentration correction has been completed and the symbol “Table1[ ][ ]” indicates the correction table of the base concentration. Also, the term “Dsc>>3” indicates a shift by 3 bits in a right direction. The table is selected depending on the base hue discriminated by the discriminating portion 213. The process is executed by the base concentration correction table selection portion 291.

Subsequently, the concentration correction when a character is determined will be described in detail. Also for the character region, the following operation (equation) is executed like as the case of the base concentration correction.
BKout=Table2[Dsc & 000111][BK]
where the term “Table2[ ][ ]” indicates the correction table of the character region. Also, the term “Dsc & 000111” indicates a takeout of three lowmost bits of the Dsc signal. The table is selected depending on the character hue discriminated by the discriminating portion 213. This processing is executed in the character concentration correcting portion 292.

With the configuration as above, it is possible to select a suitable concentration correction table for each color for the base concentration correction or the character concentration correction, thereby enabling the contrast between the base concentration and the character concentration to be enhanced. Also, in order to correct CMY signals, a correction table for each color signal is selected from the CMY correction table 295 and then the following operation equations are executed by the CMY correcting portion 294.

Cout = Tablec[C]
Mout = Tablem[M]
Yout = Tabley[Y]

Next, an operation of the monochromatic correction processing during the copying operation and the network scanning operation according to the present invention will be described in detail. In the copying operation, it is possible from the control panel to set a character mode (putting stress on contrast) giving priority to reproduction of a character image and a picture mode giving priority to a picture quality.

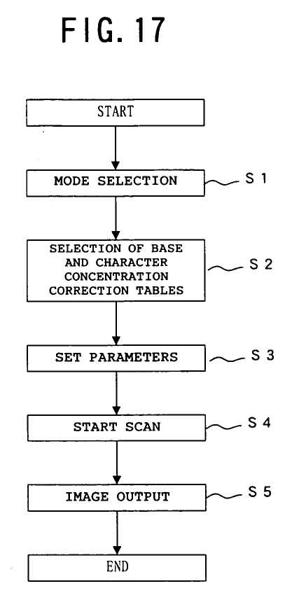

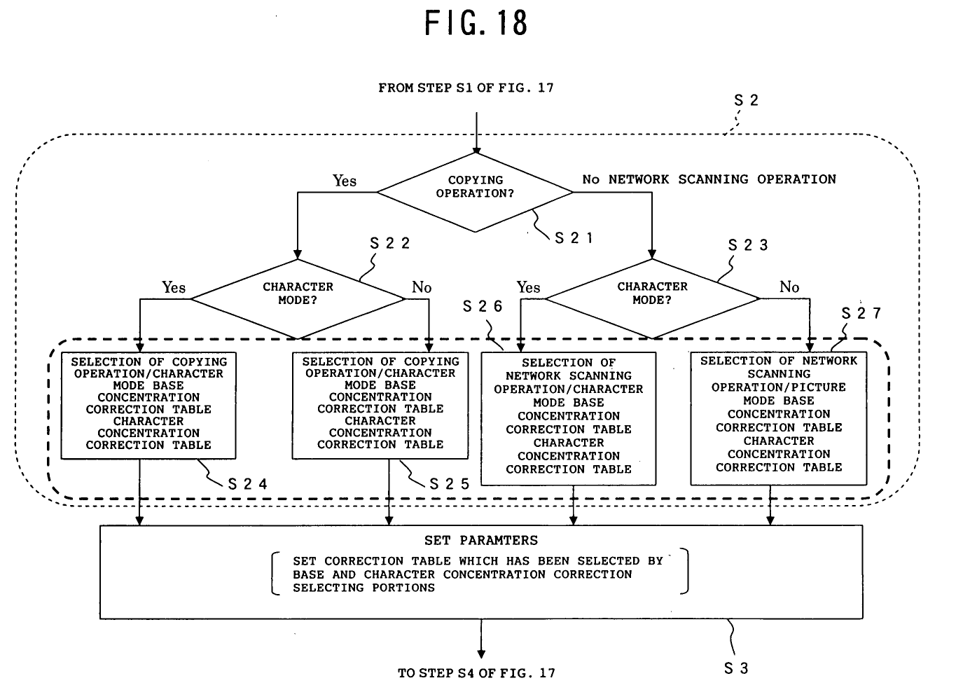

FIG. 17 is a schematic flow chart of a processing flow for each operation of various modes. After a mode and the like are firstly selected on the control panel (S1), abase concentration correction table and a character concentration correction table are selected by a system CPU (S2). Values of respective concentration correction tables which have been calculated by the system CPU and various parameters for the discriminating portion 213 are set for each processing block (S3). After the parameters have been set, a scanning operation is started to read image data placed on the document glass for executing the discrimination processing and the concentration correction processing (S4). After various image processing operations such as the concentration correction processing have been completed, the image forming operation is performed in the engine portion to output an image (S5).

The processing operations in the steps S2 and S3 will be described in detail with reference to a schematic flow chart of FIG. 18.

After a mode and the like are selected on the control panel (S1), it decided whether an operation requested via the control panel from a user is the “copying operation” or the “network scanning operation” (S21).

Here, in the event that the “copying operation” is requested (S21: Yes), it is decided whether the mode that has been set in the step S1 as described above is the “character mode” or the “picture mode” (S22).

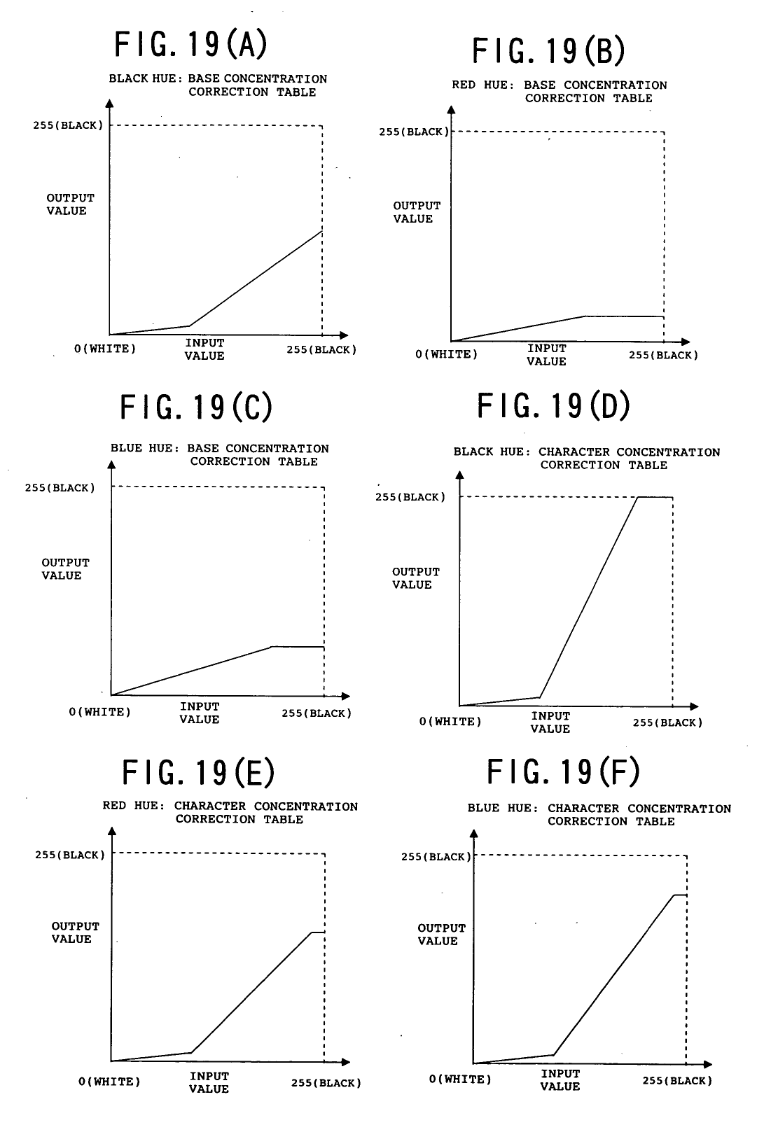

In the event that the “character mode” is selected (S22: Yes), the base concentration correcting table selection portion 291 and the character concentration correcting table selection portion 292 select a corresponding one of the base and character concentration correction tables prepared for the “copying operation” in the “character mode” to the color information of pixels as an object to be corrected in concentration (S24). FIG. 19(A) to FIG. 19(C) show exemplified base concentration correction tables and FIG. 19(D) to FIG. 19(F) show exemplified character concentration correction tables.

On the other hand, in the event that the “picture mode” is selected (S22: No), the base concentration correcting table selection portion 291 and the character concentration correcting table selection portion 292 select a corresponding one of the base and character concentration correction tables prepared for the “copying operation” in the “picture mode” to the color information of pixels as an object to be corrected in concentration (S25).

Also, in the event that the “network scanning operation” is requested (S21: No), it is decided whether the mode that has been set in the step S1 as described above is the “character mode” or the “picture mode” (S23).

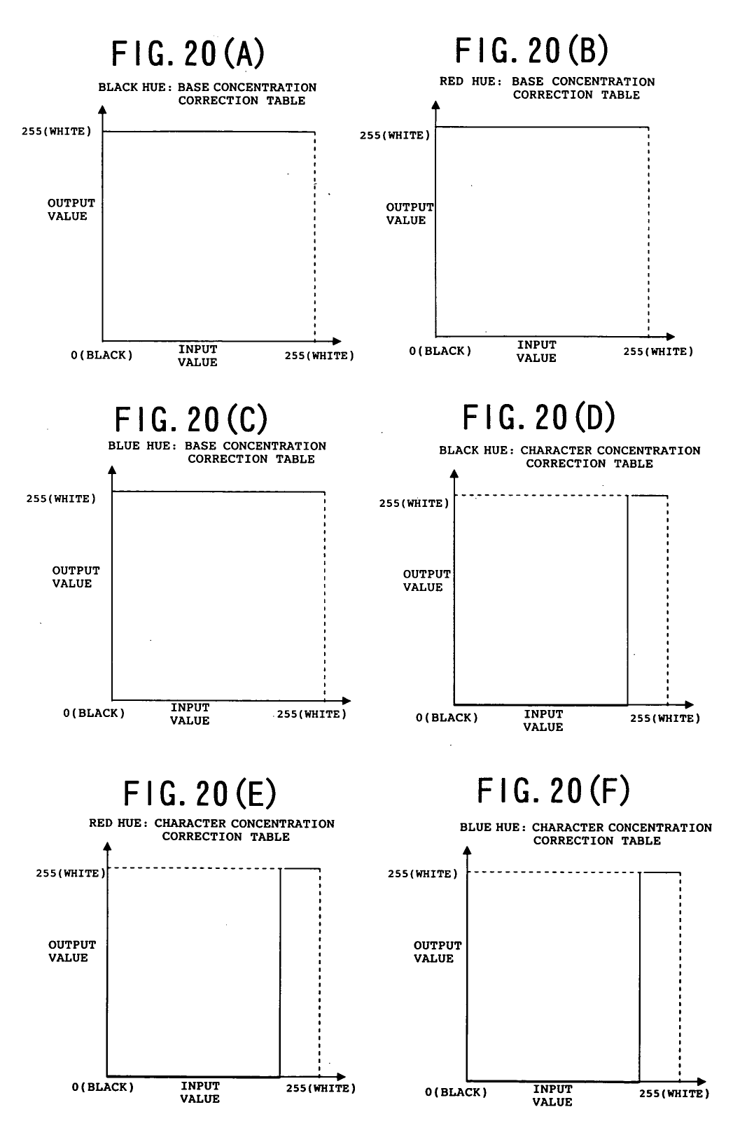

In the event that the “character mode” is selected (S23: Yes), the base concentration correcting table selection portion 291 and the character concentration correcting table selection portion 292 select a corresponding one of the base and character concentration correction tables prepared for the “network scanning operation” in the “character mode” to the color information of pixels as an object to be corrected in concentration (S26). FIG. 20(A) to FIG. 20(C) show exemplified base concentration correction tables and FIG. 20(D) to FIG. 20(F) show exemplified character concentration correction tables.

On the other hand, in the event that the “picture mode” is selected (S23: No), the base concentration correcting table selection portion 291 and the character concentration correcting table selection portion 292 select a corresponding one of the base and character concentration correction tables prepared for the “copying operation” in the “picture mode” to the color information of pixels as an object to be corrected in concentration (S27).

It should be noted that only tables corresponding to the black, red and blue hues are illustrated, respectively, for each of the base concentration correction table and the character concentration correction table. However, the present invention should not be limited to those. Depending on operation contents (the copying operation, the network scanning operation and the like) and operation modes (the character mode, the picture mode and the like), the correction tables of 7 colors in total: Cyan, Magenta, Yellow, Black, Red, Green, and Blue) may be prepared and stored in the memory. Accordingly, if two kinds of the operation contents such as the “copying operation” and the “network scanning operation” as the operation contents and two kinds of the operation modes such as the “character mode” and the “picture mode” are set, the correction tables will count up to: 2(kinds of operation contents)×2(kinds of operation modes)×7(kinds of colors)=28. As described above, predetermined rules are defined in the correction tables in this embodiment. However, the present invention should not be limited to those. For example, it is possible in the present invention to represent correction rules relative to the luminance by operation equations such as functions.

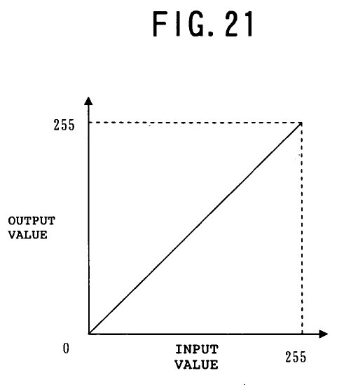

Incidentally, in the above-mentioned step S2 of correction table selection, when an object is determined as a picture by the base color determination 223 or the “picture mode” is being selected, its gradation is regarded as important so that the base concentration correction table as shown in FIG. 21 is selected. Particularly, in the picture mode, the setting of the discriminating portion 213 is turned off and the monochromatic concentration correcting portion performs its correction only by the base concentration correction table (FIG. 21). That is, one predetermined correction rule corresponding to the character region as a specific region and another predetermined correction rule corresponding to the picture region as a specific region are configured to be different in correction content of pixel luminance information.

Also, a “image output for OCR” and a “image output mode for a picture image” are prepared for the “network scanning operation” and can be set on the control panel.

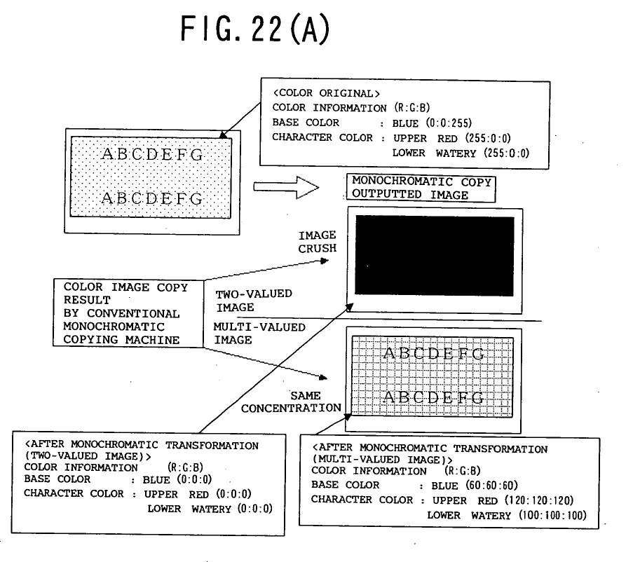

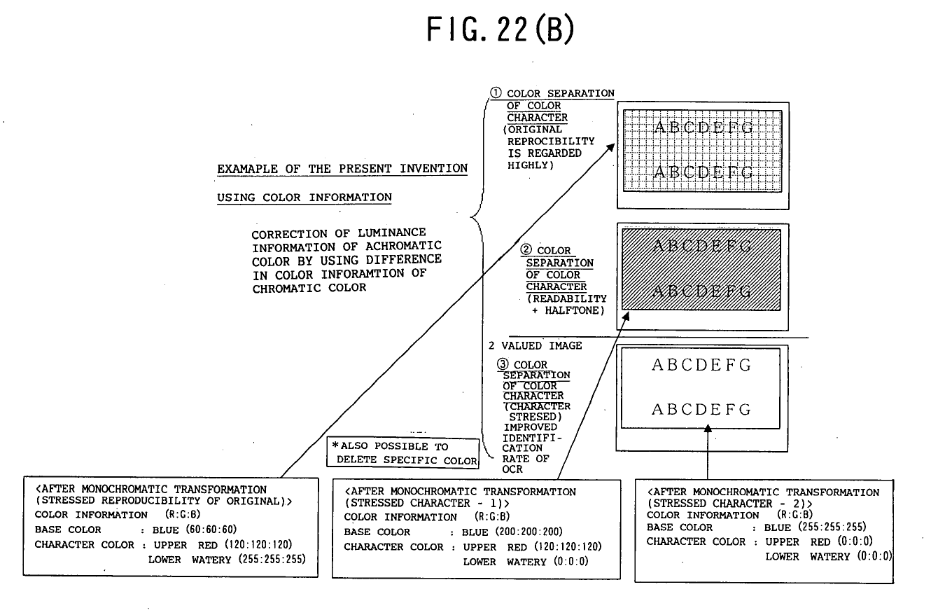

FIGS. 22(A) and 22(B) show a specific example of effective actions at the time of copying operation according to the present invention.

In the event that a color original ORG has a base of blue color (color information R: 0, G: 0, B: 255), upper-row characters of red color (color information R: 255, G: 0, B: 0), and lower-row characters of watery color (color information R: 50, G: 100, B: 255), data conversion processing, concentration transformation processing and the like are performed for the monochromatic copying to output a binarized image. Depending on threshold values for binarization of an image, all of colors of the base, upper-row and lower-row characters may reach 255 as the highest concentration data, as a result of which the information of the color original ORG may be black wholly with the lack of character information. In the event that any suitable processing is performed for generating multi-value output to reproduce a halftone, the concentration data of the base, upper-row characters and lower-row characters are 80:50:45, as a result of which there still exists a difference in concentration (contrast) between the base and the characters but the concentration data values of the upper-row characters and lower-row characters may be approximate to each other, thereby raising a problem where the upper-row characters and lower-row characters can be printed at the same concentration.

In the present invention, if a reproducibility of the color original ORG in which a printing is performed to be propositional to the color information of the color original is regarded highly, it is possible to provide differences in concentration among the base, upper-row and lower-row characters for example by setting the base concentration data to 80, the upper-row character data to 50, the lower-row character data to 0, respectively, and then obtain a printing result where differences in the color information thereof are take into consideration.

Also, if written character information is regarded highly in comparison with the base, it is possible to provide differences in concentration among the base, upper-row and lower-row characters for example by setting the base concentration data to 40, the upper-row character data to 80, the lower-row character data to 255, respectively, and then obtain a printing result where differences in the color information thereof are take into consideration and the written character information is emphasized.

Further, if the base color is deleted and only the character color is emphasized, it is possible to obtain a printing result where only the character information is emphasized by setting the base concentration data to 0, the upper-row character data to 255, the lower-row character data to 255, respectively.

On the other hand, it is possible to limit an object to be subjected to the correction processing of luminance in the monochromatic correcting portion to either of the base, upper-row character and lower-row character, or any color (a specified color) based on an operation input by the user externally or from the control panel. This enables the monochromatic correction having a high degree of freedom to be performed.

In the description as above, the highest concentration is set to 255 but it is possible to set to 1023 in the case of 10-bit data. Also, as a light emitting amount or a light emitting period of time of the semiconductor laser becomes bigger, it becomes possible to reproduce black color as the high concentration. Therefore, in the description as above, a high concentration image can be obtain by bigger concentration data. However, needless to say, it is possible to obtain a higher concentration as the concentration data becomes smaller.

Thus, with a suitable processing operation in the above described processing operations, it is possible to obtain an image of only characters without the base, and therefore its binarization processing can readily be performed. As a result, it is possible to facilitate a decrease of data capacity and realize an effective data communications via the image reading apparatus (scanner) connected to a network. Also, it is possible to facilitate a further decrease of data capacity by using the compression processing operation.

Also, in the event that the image forming apparatus is utilized as a network scanner via a network, image data for three colors of RGB is required by the network scanner to read a color original. It needs an enormous amount of data capacity. According to the present invention, when it is desired to transform a color original into a monochromatic image only composed of B/W signals and file it, it is possible to obtain a high picture-quality monochromatic image with a small data capacity and excellent in easy character-discrimination.

Here, the specific example will be shown below.

In the event that a color original ORG has a base of blue color (color information R: 0, G: 0, B: 255), upper-row characters of red color (color information R: 255, G: 0, B: 0), and lower-row characters of watery color (color information R: 100, G: 100, B: 255), data conversion processing, concentration transformation processing and the like are performed for the monochromatic copying to output a binarized image. Depending on threshold values for binarization of an image, all of colors of the base, upper-row and lower-row characters may reach 0 as the lowest luminance data, as a result of which the information of the color original ORG may be black wholly with the lack of character information. In the event that any suitable processing is performed for generating multi-value output to reproduce a halftone, the luminance data of the base, upper-row characters and lower-row characters are 60:120:100, as a result of which there still exists a difference in luminance (contrast) between the base and the characters but the luminance data values of the upper-row characters and lower-row characters may be approximate to each other, thereby raising a problem where the upper-row characters and lower-row characters can be printed at the same concentration.

In the present invention, if a reproducibility of the color original ORG in which a printing is performed to be propositional to the color information of the color original is regarded highly, it is possible to provide differences in luminance among the base, upper-row and lower-row characters for example by setting the base concentration data to 60, the upper-row character data to 120, the lower-row character data to 255, respectively, and then obtain a printing result where differences in the color information thereof are take into consideration.

Also, if written character information is regarded highly in comparison with the base, it is possible to provide differences in luminance among the base, upper-row and lower-row characters for example by setting the base luminance data to 200, the upper-row character data to 120, the lower-row character data to 0, respectively, and then obtain a printing result where differences in the color information thereof are take into consideration and the written character information is emphasized.

Further, if the base color is deleted and only the character color is emphasized, it is possible to obtain a printing result where only the character information is emphasized by setting the base luminance data to 255, the upper-row character data to0, the lower-row character data to 0, respectively.

Conventionally, the optical character recognition (OCR) was poor in identification rate relative to the chromatic color. According to the present invention, it is possible to extract only characters regardless of their color information and readily binarize the extracted result, thereby enabling the identification rate of the OCR to be improved.

In the event that the present invention is utilized at an input stage of the image forming apparatus for forming an image by using toners of-four colors (YMCK) and there is an external input to produce a monochromatic image from a color original, the image is formed by using black toner (K toner).

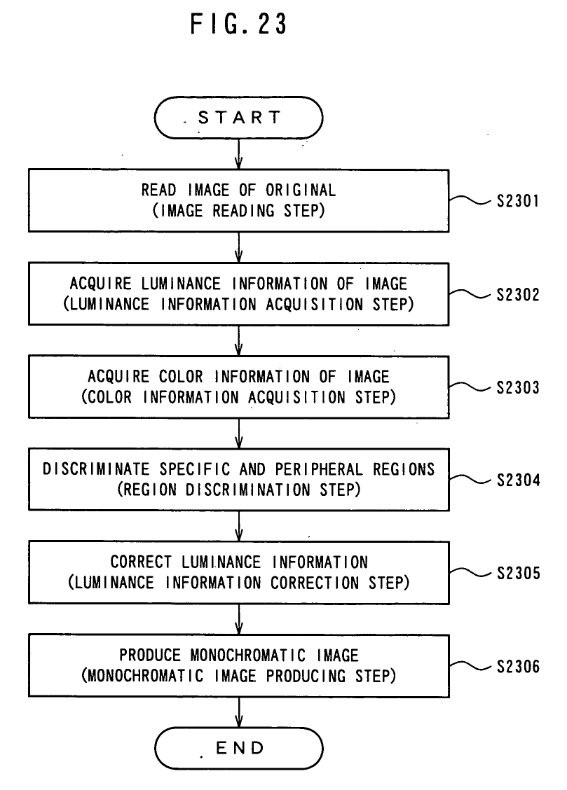

Next, an overall processing flow of the image processing apparatus according to this embodiment will be described in detail with reference to a flow chart as shown in FIG. 23.

Firstly, the image processing apparatus reads an image on an original (an image reading step) (S2301).

Subsequently, the image processing apparatus acquires luminance information of pixels forming the image (a luminance information acquisition step) (S2302) and further acquires color information of pixels forming the image (a color information acquisition step) (S2303).

In this manner, based on the acquired luminance and color information, the image processing apparatus discriminates on the image a specific region and a peripheral region adjacent to the specific region (a region discrimination step) (S2304).

In an adjacent portion between the specific region and the peripheral region, if a difference in luminance of pixels forming the specific region and the peripheral region is turned out to be less than a predetermined threshold value, the luminance information of pixels of at least one of the specific region and the peripheral region is corrected based on a predetermined condition so that the difference in luminance of pixels becomes to be more than the predetermined value (a luminance information correction step) (S2305). The correction of the pixel luminance information may be executed based on the acquired color information. In addition, the luminance information correction step may be configured to execute the correction of the luminance information of pixels of the neighborhood of a portion adjacent to the specific and peripheral regions.

Based on the read original image, a monochromatic image reflecting a correction content of the luminance information processed at the step (S2305) as described above is produced (a monochromatic image producing step) (S2306).

The above mentioned steps (S2301-S2306) can be realized by causing a computer to execute an image processing program stored in a storage region of the image forming apparatus or the image processing apparatus equipped with the former apparatus.

Incidentally, in this embodiment as described above, the function to embody the present invention has previously been stored in the apparatus. However, it is possible to download a similar function via a network to the apparatus or to install a storage medium storing therein the similar function in the apparatus. As such a storage medium, it is possible to adopt any form of a storage medium which is capable of storing a program or readable by the apparatus, such as CD-ROM or the like. Of course, the function obtainable by the previous installation or the download is cooperated with an OS in the apparatus so as to exercise that function.

Additionally the image processing apparatus of this invention can be also adapted to an image reading apparatus( scanner) or an image forming apparatus.

As described above, an image read by the image reading apparatus is separated into character and base regions based on the color information so that luminance signals of respective regions can be corrected. Therefore, it is possible to provide a high picture quality image output without any occurrence of image crush.

According to the present invention, it is possible to detect hair strokes of characters and then provide a fairly good monochromatic image in which the hair strokes of characters are emphasized. Also, depending on the user's purpose, it is possible to extract hair strokes of characters and then print only the hair strokes of characters.

In the embodiment, required processing operations are executed by using the luminance information and color information. In the event that a color original is conventionally handled as a monochromatic image in the form of electronic data for filing, the complete monochromatic image without being lack of image information can be obtained from the original such as one which has result in being lack of image information in the prior. Also, it is possible to detect hair strokes of characters and then provide a fairly good monochromatic image in which the hair strokes of characters are emphasized. Furthermore, depending on the user's purpose, it is possible to extract hair strokes of characters and then output electronic image data only for the hair strokes of characters.

In the prior art, when a color original is monochromatically duplicated, it is often difficult to separate only characters depending on the luminance information and/or color information of the base and characters. Even if such a color original is used, the image processing apparatus according to the present invention is adapted for surely extracting the character information. Then, based on that extraction result, it is possible to form an image only including hair strokes of characters, thereby enabling the image data to be easily alleviated. Furthermore, it is possible to easily binarize the image thus formed, thereby enabling the image data to be further alleviated. Also, the character recognition processing operation relative to a two-valued image can be performed by the OCR and the like, thereby substantially improving the identification rate as compared to the prior art.

Thus, according to the present invention as described above, it is possible to provide a technology by which a fairly good monochromatic image without any picture quality deterioration can be obtained from a color image original.

What is claimed is:

1. An image processing apparatus, comprising:
a luminance information acquiring portion adapted for acquiring luminance information of pixels forming an image;
a color information acquiring portion adapted for acquiring color information of pixels forming the image; and
a luminance information correcting portion adapted for executing a correction of said luminance information of pixels acquired by said luminance information acquiring portion based on said color information of pixels acquired by said color information acquiring portion.

2. The image processing apparatus according to claim 1,
characterized in that said luminance information correcting portion has plural correction tables, selects a correction table from said plural correction tables corresponding to said color information of pixels acquired by said color information acquiring portion, and corrects said luminance information of pixels acquired by said luminance information acquiring portion by using said selected correction table.

3. The image processing apparatus according to claim 1,
characterized by further comprising a discriminating portion that discriminates plural regions of said image,
wherein said correcting portion has plural correction tables corresponding to each region of said plural regions, corrects said luminance information of pixels of each region of said plural regions respectively by using said correction tables corresponding to each region of said plural regions.

4. The image processing apparatus according to claim 3,
characterized in that said correction portion has plural correction tables corresponding to plural regions and plural color information, selects one table from said plural correction tables, and corrects said luminance information of pixels of each region of said plural regions respectively by using said correction tables corresponding to each region of said plural regions.

5. The image processing apparatus according to claim 4,
characterized in that said plural regions include a first region consisting of a character region and a base region consisting of a non-character region.

6. The image processing apparatus according to claim 1,
characterized by further comprising image forming portion that forms images by using said luminance information of pixels corrected by said correcting portion.

7. The image processing apparatus according to claim 6,
characterized by further comprising plural image forming modes selectively to be able to execute the image processing apparatus forms images by said image forming portion,
wherein said correcting portion comprises plural sets of correction tables corresponding to said plural image forming modes respectively, and selects a set of correction tables corresponding to said image forming mode selected by said image forming portion.

8. The image processing apparatus according to claim 1,
wherein said luminance information acquiring portion is constructed with a first line sensor which does not have a transparent filter or a color filter on its surface so as to acquire said luminance information composing said pixels,
said color information acquiring portion is constructed with a second line sensor which has a color filter on its surface so as to acquire said color information, and said first line sensor and said second line sensor constructs a image reading apparatus.

9. The image processing apparatus according to claim 8,
characterized in that said second line sensor consists of three line sensors which have R,G,B color filters respectively.

10. An image processing program that is executed by a computer, comprising:
a luminance information acquiring step adapted for acquiring luminance information of pixels forming an image;
a color information acquiring step adapted for acquiring color information of pixels forming the image; and
a luminance information correcting step adapted for executing a correction of said luminance information of pixels acquired by said luminance information acquiring portion based on said color information of pixels acquired by said color information acquiring portion.

11. The image processing program according to claim 10,
characterized in that said luminance information correcting step selects a correction table from plural correction tables corresponding to said color information of pixels acquired by said color information acquiring portion, and corrects said luminance information of pixels acquired by said luminance information acquiring portion by using said selected correction table.

12. The image processing apparatus according to claim 10,
characterized by further comprising a discriminating step that discriminates plural regions of said image,
wherein said correcting step corrects said luminance information of pixels of each region of said plural regions respectively by using said correction tables corresponding to each region of said plural regions.

13. The image processing program according to claim 10,
further comprising image forming step that forms images by using said luminance information of pixels corrected by said correcting step.
